(19) United States
(12) Patent Application Publication
(10) Pub. No.: US 2012/0242451 A1
(43) Pub. Date: Sep. 27, 2012

(54) GENERATOR SYSTEM MONITORING APPARATUS AND COMPUTER READABLE MEDIUM

(76) Inventors: Yasuyuki TANAKA, Chigasaki-Shi (JP); Keiichi Teramoto, Tokyo (JP); Kazutaka Ohigashi, Yokohama-Shi (JP)

(21) Appl. No.: 13/308,740

(22) Filed: Dec. 1, 2011

(30) Foreign Application Priority Data
Mar. 25, 2011 (JP) 2011-67163

(51) Int. Cl. G06F 19/00; G01R 31/40; G05B 23/02

(52) U.S. Cl. 340/3.1; 702/58

(57) ABSTRACT

There is provided a generator system monitoring apparatus for a generator system including a generator, a first measuring apparatus and a second measuring apparatus. A power-generation state determining unit determines whether the generator is generating the electric power or not. A measurement information acquiring unit acquires, when it is determined the generator is not generating the electric power, a first measurement value and a second measurement value from the generator system, the first measuring apparatus measuring electric power generated by the generator to obtain the first measurement value, and the second measuring apparatus measuring the electric power generated by the generator to obtain the second measurement value. A system state determining unit determines whether the first measuring apparatus has an abnormality or not by comparing the first measurement value and the second measurement value with each other.

### CROSS REFERENCE TO RELATED APPLICATIONS

This application is based upon and claims the benefit of priority from the prior Japanese Patent Application No. 2011 67163, filed on Mar. 25, 2011, the entire contents of which are incorporated herein by reference.

### FIELD

Embodiments of the present invention relate to a generator system monitoring apparatus and a computer readable medium for a generator system such as a solar power generating system.

### BACKGROUND

Conventionally, there is known a monitoring apparatus that determines occurrence of an abnormality in a solar cell if the electric power generated by the solar cell in a generator system is changed by a predetermined degree or higher and determines normality if there is no such change. If the abnormality is detected by the monitoring apparatus, this fact is displayed by using a display apparatus.

However, in the generator system, if a memory unit, which records the data of the electric power generated by solar power, or a processing unit, which calculates the data of the electric power generation, is malfunctioning, the monitoring apparatus cannot correctly determine the state of the solar cell. For example, even in the case in which the amount of electric-power generation of the solar cell is changed by the predetermined degree or higher, the abnormal state cannot be determined if the data of the electric power generation is not correctly recorded. In this case, the malfunction of the memory unit or the processing unit has to be detected, and a countermeasure such as replacement or repairing has to be promptly carried out.

### BRIEF DESCRIPTION OF THE DRAWINGS

FIG. 1 is an overview drawing showing an overall configuration of a power generation monitoring system according to a first embodiment;

FIG. 2 is a flow chart showing a processing procedure of the first embodiment;

FIG. 3 is a sequence diagram of the first embodiment;

FIG. 4 is a configuration diagram of the generator system monitoring apparatus according to the first embodiment;

FIG. 5 is a sequence diagram of a second embodiment;

FIG. 6 is a sequence diagram of a third embodiment; and

FIG. 7 is an overview drawing showing an overall configuration of a power generation monitoring system according to a fourth embodiment.

### DETAILED DESCRIPTION

According to an embodiment of the present invention, there is provided a generator system monitoring apparatus for a generator system. The generator system includes a generator, a first measuring apparatus and a second measuring apparatus.

The generator system monitoring apparatus includes a power-generation state determining unit, a measurement information acquiring unit and a system state determining unit.

The power-generation state determining unit determines whether the generator is generating the electric power or not.

The measurement information acquiring unit acquires, when it is determined that the generator is not generating the electric power, a first measurement value and a second measurement value from the generator system. The first measuring apparatus measures electric power generated by the generator to obtain the first measurement value. The second measuring apparatus measures the electric power generated by the generator to obtain the second measurement value.

The system state determining unit determines whether the first measuring apparatus has an abnormality or not by comparing the first measurement value and the second measurement value with each other.

Hereinafter, the embodiments of the present invention will be explained with reference to drawings.

### First Embodiment

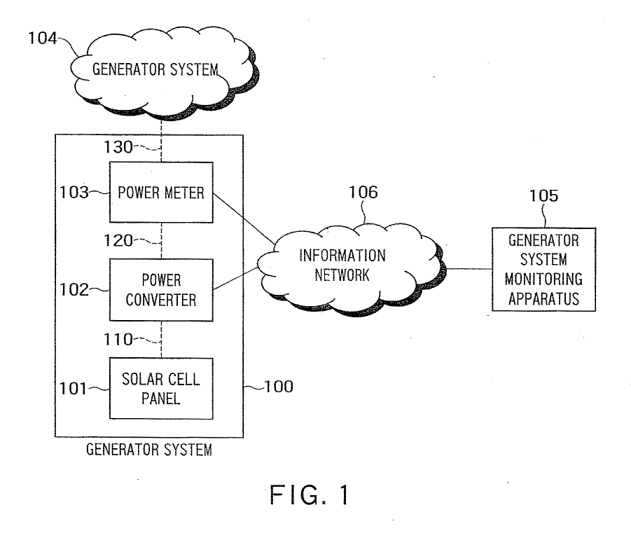

FIG. 1 shows an overall configuration of a power generation monitoring system provided with a generator system monitoring apparatus according to the first embodiment.

A generator system 100 is composed of a generator 101, a power converter (first measuring apparatus) 102, and a power meter (second measuring apparatus) 103. The generator system 100 is disposed, for example, in a house in which a user lives or a corporate building. The power meter 103 is a power meter which has passed the inspection of, for example, Japan Electric Meters Inspection Corporation and can be used for billing. In the present example, a solar cell panel is used as the generator, but may be, for example, a wind generator or a storage battery.

Each of the part between the solar cell panel 101 and the power converter 102, the part between the power converter 102 and the power meter 103, and the part between the power meter 103 and a power system 104 in an upper level thereof is electrically connected.

Each of the generator system monitoring apparatus 105, the power converter 102, and the power meter 103 is connected to an information network 106. The generator system monitoring apparatus 105 can communicate with the power converter 102 and the power meter 103 via the information network 106. The information network 106 may be a large-scale network such as the Internet or a telephone network or may be a small-scale network such as a home network.

The solar cell panel 101 generates electric power as a direct current and causes the generated direct-current power to flow toward a connection 110.

The power converter 102 converts the direct-current power, which is obtained from the connection 110, to alternating-current power and causes the alternating-current power to flow toward a connection 120. The power converter 102 also measures the alternating-current power caused to flow to the connection 120 and obtains a power amount measurement value (first measurement value). The power amount measurement value may be anything as long as the value is a value capable of specifying the amount of the alternating-current power flowed to the connection 120, and, in this case, the value is the cumulative amount of electric power. Other than the cumulative amount of electric power, for example, a time-averaged value may be used. The measurement by the power converter 102 may be reset at every constant period of time or predetermined timing specified from outside.

The power meter 103 receives the alternating-current power, which is obtained from the connection 120, measures the received alternating-current power, and obtains a power amount measurement value (second measurement value). The power amount measurement value may be anything as long as the value is a value capable of specifying the amount of the alternating-current power received from the connection 120, and, in this case, the value is the cumulative amount of electric power. Other than the cumulative amount of electric power, for example, a time-averaged value may be used. After the measurement, the power meter 103 causes the alternating-current power to flow toward a connection 130. As well as the power converter 102, the measurement by the power meter 103 may be reset at every constant period of time or predetermined timing specified from outside.

The power converter 102 notifies the generator system monitoring apparatus 105 of power-generation state information 141 via the information network 106. The power-generation state information 141 is the information indicating whether the solar cell panel 101 is currently generating electric power or not. As a method to determine whether the solar cell panel 101 is generating electric power or not, it may be determined that electric power is not being generated when the direct current input from the solar cell panel 101 to the power converter 102 is zero, and it may be determined that electric power is being generated when the direct current is larger than zero. Alternatively, the power converter 102 may receive a value, which indicates whether electric power is being generated or not, from the solar cell panel 101, and whether electric power is being generated or not may be determined based on the value. The timing to notify the generator system monitoring apparatus 105 may be at the point when a power-generation state information request is received from the generator system monitoring apparatus 105, or it may be spontaneously transmitted when the power generation state of the solar cell panel 101 is changed (“generating power” to “power generation cessation” or “power generation cessation” to “start power generation”).

When the power converter 102 receives a measurement information request from the generator system monitoring apparatus 105 via the information network 106, the power converter 102 notifies the generator system monitoring apparatus 105 of measurement information 140. The measurement information 140 includes at least the latest power amount measurement value measured by the power converter 102. The measurement information 140 may further include the measurement value, voltage value, and/or current value of the direct-current power.

When the power meter 103 receives a measurement information request from the generator system monitoring apparatus 105 via the information network 106, the power meter 103 notifies the generator system monitoring apparatus 105 of measurement information 150. The measurement information 150 includes at least the latest power amount measurement value measured by the power meter 103. The measurement information 150 may include a voltage value and/or a current value.

The generator system monitoring apparatus 105 acquires the power-generation state information 141 from the power converter 102 and, based on the acquired power-generation state information 141, determines whether the generator 101 has currently ceased power generation or not. If electric power generation has been currently ceased, the measurement information 140 and the measurement information 150 is acquired from the power converter 102 and the power meter 103, respectively, and the cumulative amounts of electric power included in the measurement information 140 and the measurement information 150 are compared with each other, thereby determining whether the power converter 102 has an abnormality or not. If the power converter 102 is normal, abnormality determination of the generator 101 is also carried out based on the current value or voltage value at least included in the measurement information 140.

Generally, the power meter that can be used for billing has high precision of measurement and is highly reliable. Therefore, when the generator system monitoring apparatus acquires the measurement information from the power converter and the power meter and compares the power amount measurement values (herein, cumulative amounts of electric power) included in the respective measurement information with each other, the state of the power converter can be determined. More specifically, the power converter can be determined to be normal if the difference between the cumulative amounts of electric power is within a predetermined range, and the power converter can be determined to be abnormal if the difference between the cumulative amounts of electric power falls outside the predetermined range.

However, normally, in order to appropriately carry out the comparison of the cumulative amounts of electric power, the measurement information has to include the cumulative amount of electric power and the points of time at which the values are measured, and the values at the same point of time (if there is a time lag in the measurement, the points of time delayed/advanced by the lag) have to be used. In order to do this, clocks in the power converter 102 and the power meter 103 have to be synchronized. Particularly, when the case in which the amount of electric power generated by the solar cell panel can be rapidly changed due to, for example, the amount of solar radiation is taken into consideration, a highly-precise time synchronizing process is essential between the measurement information 140 and the measurement information 150. However, there is a problem that high implementation cost is taken in order to realize the highly-precise time synchronizing process.

Therefore, in the present embodiment, power generation cessation of the generator is detected, and the latest power amount measurement values acquired from the power converter 102 and the power meter 103 after the power generation is ceased are compared with each other. Therefore, abnormality of the power converter 102 can be determined without carrying out the time synchronizing process between the power converter 102 and the power meter 103.

Hereinafter, details of the operation by the generator system monitoring apparatus 105 will be explained.

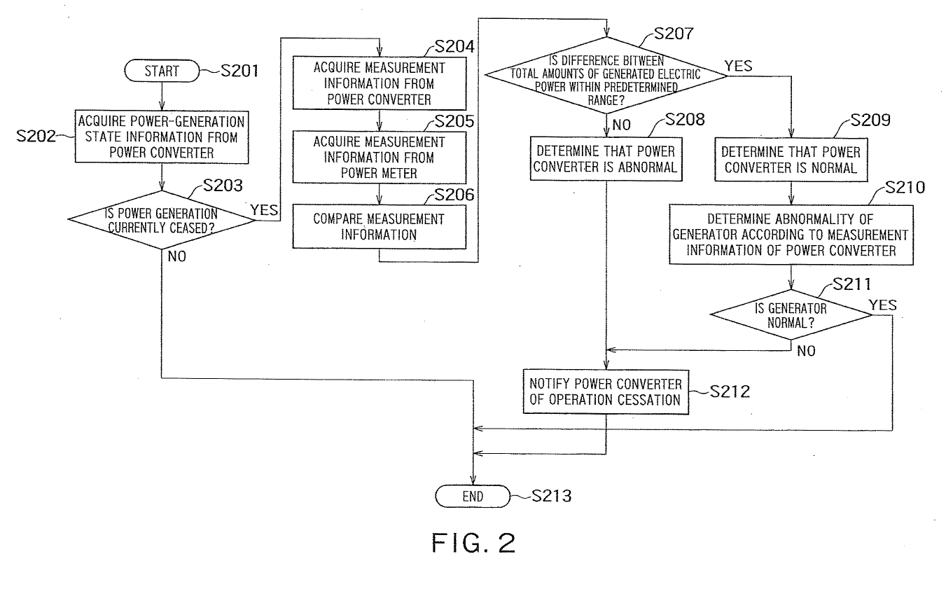

FIG. 2 is a flow chart showing an operating procedure of the generator system monitoring apparatus 105.

When the generator system monitoring apparatus 105 starts a generator system state determining process (S201), the generator system monitoring apparatus 105 transmits the power-generation state information request, thereby acquiring the power-generation state information 141 from the power converter 102.

The power-generation state information 141 includes at least the information that whether the solar cell panel 101 is currently generating electric power or not. The generator system monitoring apparatus 105 references the power-generation state information 141 and determines whether the solar cell panel 101 has currently ceased power generation or not (S203).

If it is determined that power generation is not currently ceased as a result of S203, in other words, if electric power is being generated, the generator system state determining process is terminated (S213).

If it is determined that power generation is currently ceased as a result of S203, the generator system monitoring apparatus 105 transmits the measurement information request, thereby acquiring the measurement information 140 from the power converter 102 (S204).

Then, the generator system monitoring apparatus 105 transmits the measurement information request, thereby acquiring the measurement information 150 from the power meter 105 (S205).

Then, the generator system monitoring apparatus 105 compares the cumulative amount of electric power included in the measurement information 140 and the cumulative amount of electric power included in the measurement information 150 with each other (S206).

If the difference between the values of the cumulative amounts of electric power (total amounts of generated electric power) is not within a predetermined range as a result of the comparison of S206 (“no” in S207), in other words, if the difference between the values of the total amounts of generated electric power falls outside the predetermined range, it is determined that the power converter 102 has abnormality (S208). Then, the power converter 102 is notified of an operation ceasing message (S212), and the generator system state determining process is terminated (S213).

If the difference between the values of the total amounts of generated electric power is within the predetermined range as a result of the comparison of S206 (“yes” in S207), it is determined that the power converter 102 is normal (S209), and abnormality determination of the generator (solar cell panel) 101 is carried out, for example, by evaluating power quality or determining whether the rated output of the generator 101 is satisfied or not based on the direct-current power value, the voltage value, or the current value included in the measurement information 140 (S210).

If the generator (solar cell panel) 101 is determined to be abnormal as a result of S210, the power converter 102 is notified of an operation ceasing message (S212), and the generator system state determining process is terminated (S213).

If the generator 101 is determined to be normal as a result of S210, the generator system state determining process is terminated (S213).

When the power converter 102 or the generator 101 is determined to be abnormal as a result of the generator system state determining process, in addition to cessation of the operation of the power converter 102, a process against the abnormality for preventing accidents such as an order to shut off a circuit of the generator 101 or a notification to outside may be carried out.

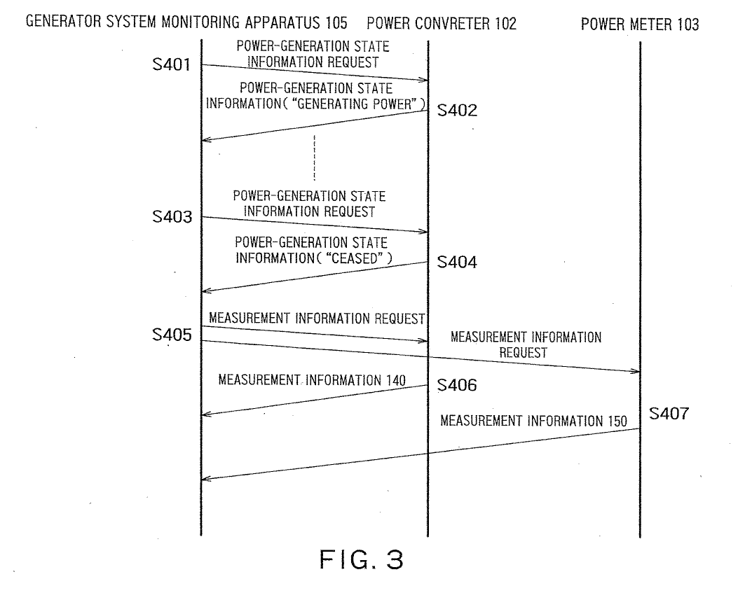

FIG. 3 shows a communication sequence between the generator system monitoring apparatus 105, the power converter 102, and the power meter 103.

First, the generator system monitoring apparatus 105 transmits the power-generation state information request to the power converter 102 (S401).

When the power converter 102 receives the power-generation state information request, the power converter 102 transmits the power-generation state information to the generator system monitoring apparatus 105 (S402).

If the power-generation state information indicating that the generator is generating electric power is transmitted in S402, the generator system monitoring apparatus 105, which has received the power-generation state information, transmits the power-generation state information request to the power converter 102 after a predetermined period of time (S403).

Similar to S402, when the power converter 102 receives the power-generation state information request, the power converter 102 transmits the power-generation state information to the generator system monitoring apparatus 105 (S404).

When the power-generation state information indicating that the generator has ceased power generation is transmitted in S404, the generator system monitoring apparatus 105 determines that the generator 101 is currently not generating electric power. Then, the measurement information requests are transmitted to the power converter 102 and the power meter 103 (S405).

The power converter 102 and the power meter 103, which have received the measurement information requests, respectively transmits the measurement information 140 and the measurement information 150 to the generator system monitoring apparatus 105 (S406, S407). When the measurement information 140 and the measurement information 150 are received, the generator system monitoring apparatus 105 determines the state of the generator system 100.

FIG. 3 shows the example in which the power converter 102 transmits the power-generation state information after the power-generation state information request is received. However, the power-generation state information may be spontaneously transmitted when the power-generation state is changed (“power generation” to “power generation cessation” or “power generation cessation” to “power generation”).

Moreover, in FIG. 3, the generator system monitoring apparatus 105 transmits the measurement information request immediately after the power-generation state information indicating power generation cessation is received; however, the measurement information request may be transmitted after the power-generation state information indicating power generation cessation is continuously received a predetermined number of times (in other words, after it is confirmed that the power-generation ceased state is stabilized).

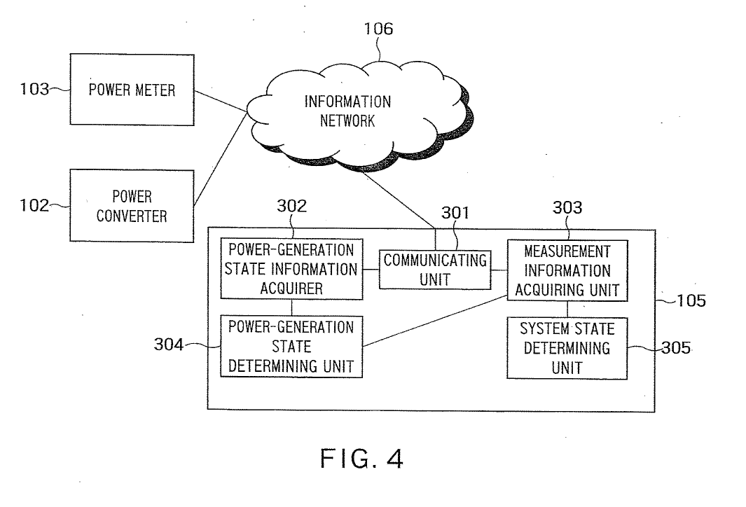

FIG. 4 shows a configuration of the generator system monitoring apparatus 105.

The generator system monitoring apparatus 105 is provided with a communicating unit 301, a power-generation state information acquirer 302, a measurement information acquiring unit 303, a power-generation state determining unit 304, and a system state determining unit 305.

The communicating unit 301 carries out communication with the power converter 102 and the power meter 103 connected to the information network 106.

The power-generation state information acquirer 302 transmits the power-generation state information request to the power converter 102 via the communicating unit 301 and acquires the power-generation state information from the power converter 102.

The measurement information acquiring unit 303 transmits the measurement information requests to the power converter 102 and the power meter 103 via the communicating unit 301 and acquires the measurement information from each of them.

The power-generation state determining unit 304 determines whether the generator (solar cell panel 101) is generating electric power or not according to the power-generation state information acquired by the power-generation state information acquirer 302. When it is determined that the generator 101 is not generating electric power, the power-generation state determining unit 304 instructs the measurement information acquiring unit 303 to acquire the measurement information from the power converter 102 and the power meter 103.

The system state determining unit 305 carries out abnormal determination of the power converter 102 and the generator 101 according to the measurement information of the power converter 102 and the power meter 103 acquired by the measurement information acquiring unit 303.

As described above, according to the present embodiment, abnormality of the power converter and the generator can be detected without a time synchronizing mechanism.

### Second Embodiment

The second embodiment is characterized by carrying out correction of the power amount measurement value of the power converter 102 when the power converter 102 is determined to be normal in S209 of the first embodiment. Specifically, the power amount measurement value obtained by the power converter 102 is caused to match the power amount measurement value obtained by the power meter 103.

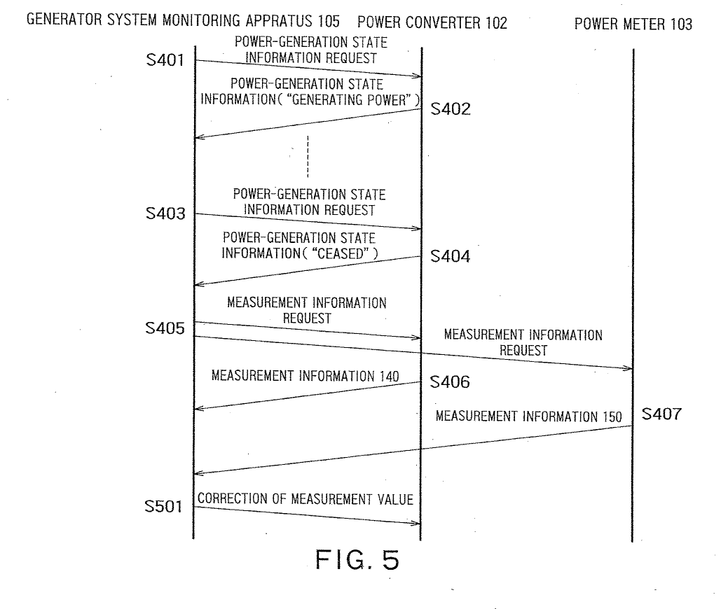

FIG. 5 shows a sequence diagram of the second embodiment, wherein S401 to S407 are the same as those of FIGS. 3, and S501 is newly added.

When the generator system monitoring apparatus 105 determines that the power converter 102 is normal according to the measurement information 140 and the measurement information 150 acquired in S406 and S407, the generator system monitoring apparatus 105 transmits a correcting message to the power converter 102. The correcting message includes the power amount measurement value included in the measurement information 150 acquired from the power meter 103 or the difference between the power amount measurement values included in the measurement information 150 and the measurement information 140.

The power converter 102 corrects the power amount measurement value of its own in accordance with the value included in the correcting message. More specifically, if the correcting message includes the power amount measurement value of the power meter 103, the power converter overwrites the power amount measurement value of its own in accordance with the power amount measurement value of the power meter 103 included in the correcting message. If the correcting message includes the above described difference, the power converter adds the difference, which is included in the correcting message, to the power amount measurement value of its own.

In this manner, in the present embodiment, a measuring error of the power converter 102 is corrected. For example, a case in which a user connects a display apparatus to the power converter 102 and desires to confirm the amount of electric power generated by the generator by displaying the measurement value (cumulative amount of electric power) of the power converter 102 is presupposed. In this case, if the error in the measurement is present (if large), when the user is to sell the generated electric power to a power company, an expected income is largely different from the actual one, which causes lack of reliability of the present system. Moreover, the abnormality determination in S208 of FIG. 2 may be affected. Moreover, the error is accumulated and increased along with time passage.

Therefore, in the present embodiment, it is caused to match the measurement value of the power meter 103, which is reliable and precise, thereby correcting the measurement value of the power converter 102 and always enabling implementation of highly precise data display or highly precise abnormal determination.

### Third Embodiment

In the third embodiment, if it is determined in S203 of FIG. 2 of the first embodiment that the generator 101 is generating electric power, a power-generation ceasing message is transmitted to the generator system 100 to forcibly cease power generation.

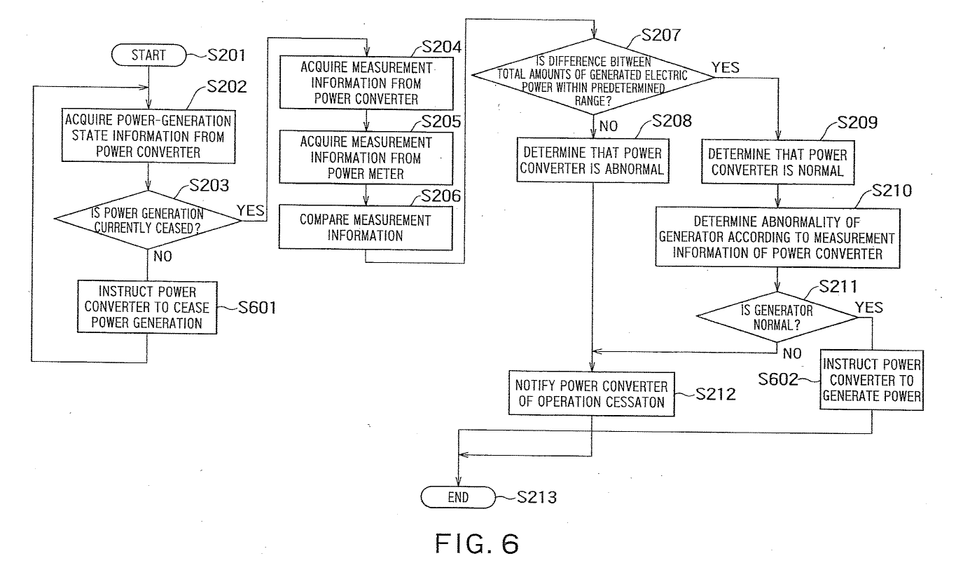

FIG. 6 shows a procedure of the third embodiment, wherein two points are different from FIG. 2.

The first point is that if it is determined in S203 that power generation is not currently ceased (no), the power converter 102 is instructed to cease the power generation (S601). More specifically, a power-generation ceasing message is transmitted to the power converter 102. The transmission of the power-generation ceasing message is carried out by a power-generation cessation transmitting unit, and the power-generation cessation transmitting unit may be incorporated in the power-generation state information acquirer 302 or the power-generation state determining unit 304 or may be present as an independent block. When the power converter 102 receives the instruction to cease power generation, the power converter ceases the generator 101.

After S601, the power-generation state information is acquired again in S202, and determination of the power-generation state is carried out in S203. Until the generator 101 ceases power generation, S202, S203, and S601 are repeated. When cessation of the power generation of the generator system 100 is reliably expected as a result of the process of S601, the process can proceed to S204 after S601 without returning to S202.

The second point is the point that, if the generator 101 is determined to be normal in S211, the power converter 102 is instructed to generate power (S602). The power converter 102, which has received the power-generation instruction, resumes power generation of the generator 101.

### Fourth Embodiment

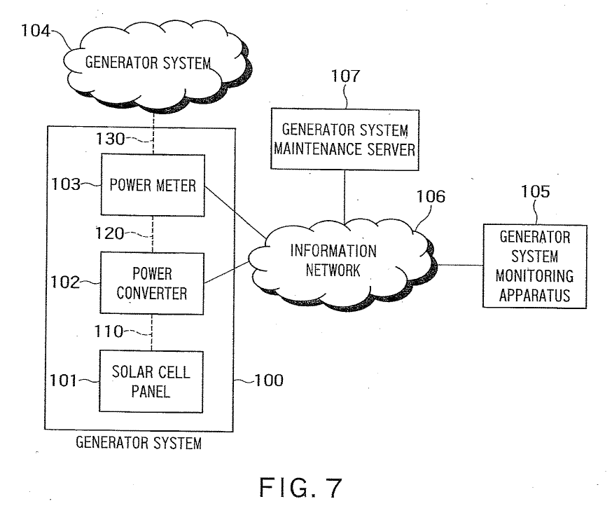

FIG. 7 shows an overall configuration of a power generation monitoring system according to the fourth embodiment. The point different from FIG. 1 is that a generator system maintenance server 107, which carries out management of the generator system, is added. The generator system maintenance server 107 is disposed, for example, in a maintenance company of the power converter 102 or the generator 101.

In FIG. 2 of the first embodiment, in S212, the generator system monitoring apparatus 105 instructs the power converter 102 to cease operation. In the fourth embodiment, in addition to that, the generator system monitoring apparatus 105 notifies the generator system maintenance server 107 of an abnormality notifying message indicating abnormality of the power converter 102 (if the power converter is determined to be abnormal in S208) or abnormality of the generator 101 (if the generator is determined to be abnormal in S210).

When the generator system maintenance server 107 is notified of the abnormality notifying message, a maintenance worker of the maintenance company contacts, for example, the user of the generator system 100 and carries out maintenance operation such as checking, modification, and/or replacement. As a result, quick restoration can be carried out, and the user is not required to contact the maintenance company by himself/herself. Therefore, a mechanism with low load can be realized.

The generator system monitoring apparatus 105 of the embodiments explained above can be also realized, for example, by using a general-purpose computer apparatus as basic hardware. More specifically, the communicating unit 301, the power-generation state information acquirer 302, the measurement information acquiring unit 303, the power-generation state determining unit 304, the system state determining unit 305, and the power-generation cessation transmitting unit of the generator system monitoring apparatus 105 can be realized by causing a processor mounted in the above described computer apparatus to execute a program. In this case, the generator system monitoring apparatus 105 may carry out the realization by installing the above described program in the computer apparatus in advance or may carry out the realization by distributing the above described program via storage in a storage medium such as a CD-ROM or via a network and arbitrarily installing the program in the computer apparatus.

1. A generator system monitoring apparatus for a generator system including a generator, a first measuring apparatus and a second measuring apparatus, comprising:
a power-generation state determining unit configured to determine whether the generator is generating the electric power or not;
a measurement information acquiring unit configured to acquire, when it is determined that the generator is not generating the electric power, a first measurement value and a second measurement value from the generator system, the first measuring apparatus measuring electric power generated by the generator to obtain the first measurement value, and the second measuring apparatus measuring the electric power generated by the generator to obtain the second measurement value; and
a system state determining unit configured to determine whether the first measuring apparatus has an abnormality or not by comparing the first measurement value and the second measurement value with each other.

2. The apparatus according to claim 1, wherein
the first measuring apparatus is a power converter configured to convert the generated electric power from a direct current electric power to an alternating current electric power and calculate the first measurement value based on the alternating current electric power after conversion; and
the second measuring apparatus is a power meter configured to calculate the second measurement value based on the alternating-current power converted by the first measuring apparatus and supply the alternating-current power to an external power system.

3. The apparatus according to claim 1, wherein,
in a case that the first measuring apparatus has the abnormality, the system state determining unit transmits an operation ceasing message to the generator system, the operation ceasing message instructing operation cessation of the first measuring apparatus.

4. The apparatus according to claim 1, wherein,
in a case that the first measuring apparatus has the abnormality, the system state determining unit transmits an abnormality notifying message of the first measuring apparatus to a generator system maintenance server managing the generator system.

5. The apparatus according to claim 1, wherein
each of the first measurement value and the second measurement value is a cumulative amount of the generated electric power.

6. The apparatus according to claim 1, wherein,
in a case that the first measuring apparatus is determined to be normal, the system state determining unit transmits a correcting message to the first measuring apparatus in the generator system, the correcting message including the second measurement value or a value of the difference between the first measurement value and the second measurement value.

7. The apparatus according to claim 1, further comprising
a power-generation state information acquirer configured to acquire power-generation state information indicating whether the generator is generating electric power or not, from the generator system; wherein
the power-generation state determining unit determines whether the generator is generating electric power or not, based on the power-generation state information.

8. The apparatus according to claim 1, wherein
the measurement information acquiring unit acquires the first measurement value and the second measurement value by transmitting a measurement information request to the generator system.

9. The apparatus according to claim 1, further comprising
a power-generation cessation transmitting unit configured to transmit a power-generation ceasing message to the generator system, the power-generation ceasing message instructing power generation cessation of the generator; and
the power-generation state determining unit examines whether the generator is generating electric power or not after the power-generation ceasing message is transmitted.

10. A non-transitory computer readable medium storing a computer program which, when executed by a computer for a generator system, causes the computer to perform steps, the generator system including a generator, a first measuring apparatus and a second measuring apparatus, the steps comprising:
determining whether the generator is generating the electric power or not;
acquiring, when it is determined that the generator is not generating the electric power, a first measurement value and a second measurement value from the generator system, the first measuring apparatus measuring electric power generated by the generator to obtain the first measurement value, and the second measuring apparatus measuring the electric power generated by the generator to obtain the second measurement value; and
determining whether the first measuring apparatus has an abnormality or not by comparing the first measurement value and the second measurement value with each other.
